(19) United States
(12) Patent Application Publication
(10) Pub. No.: US 2010/0216276 A1
(43) Pub. Date: Aug. 26, 2010

(54) Method for Electrically Connecting Photovoltaic Cells in a Photovoltaic Device

(76) Inventors: Joseph I Lichy, San Jose, CA (US); Irving Lichy, Merrica, NY (US)

Correspondence Address: Joseph I. Lichy, 1718 Mulberry Lane, San Jose, CA, 95125, US

(21) Appl. No.: 12/719,691

(22) Filed: Mar. 8, 2010

Related U.S. Application Data
(62) Division of application No. 11/372,769, filed on Mar. 10, 2006.

(51) Int. Cl. H01L 21/3205

(52) U.S. Cl. 438/80; 257/E21.294

(57) ABSTRACT

A method is disclosed for simultaneously forming the reflector of a photovoltaic concentrator and the electrical connections between a plurality of photovoltaic cells. In some embodiments a method for producing a photovoltaic device is disclosed using triangular prisms to concentrate light onto silicon cells, thereby reducing the amount of photovoltaic silicon required for generation of electrical power from sunlight without reducing the amount of light accepted by the device.

### CROSS-REFERENCE TO RELATED APPLICATION(S)

This application claims the benefit of U.S. Provisional Patent Application No. 60/660,381, filed Mar. 10^{th}, 2005. This application is a divisional application of U.S. patent application Ser. No. 11/372,769 filed on Mar. 10^{th}, 2006 asserting claims drawn to the previously nonelected invention from the reply filed on Jan. 19, 2009.

### FIELD OF INVENTION

The present invention relates to the assembly of photovoltaic cells into a photovoltaic device, more specifically, forming desired electrical connections between photovoltaic cells in a photovoltaic device.

### BACKGROUND

Photovoltaic (PV) devices convert sunlight into electricity. In their most common use they are mounted on the roofs of buildings to generate electrical power for use within that building. Though these devices are simple to use, and highly reliable, their widespread use has been hindered by their cost.

Photovoltaic (PV) devices are made up of PV cells that are electrically connected so that the device produces a convenient amount of power at a desired voltage. For instance, a typical Silicon PV cell generates power optimally at approximately 0.5V, but it may be more convenient to operate a system at 18V; in this case a PV device with 36 silicon cells electrically connected in series can be used to obtain the desired voltage. The device also serves to support and protect the silicon cells which are fragile and can degrade when exposed to moisture.

Traditionally, the electrical connection between PV cells in a device is formed by electrically conductive wires that are soldered to each cell. The process of soldering the cells to the wires is known as cell stringing, and is a costly manufacturing step.

Typically, each PV cell has two electrical connections. One on the front surface, and one on the back surface. Recently, however, several manufacturers have begun producing silicon PV cells with both electrical contacts on the back of the cell. The back contact cells generally convert light to electricity more efficiently than more traditional cells. This is because no conductors need be present on the front surface that would block light from reaching that surface, and because the internal cell structure can be modified to improve the efficiency of the photo generating process.

Referring to the publication, Simplified Module Assembly Using Back-Contact Crystalline-Silicon Solar Cells, by James M. Gee, Stephen E. Garrett and William P. Morgan, and presented at the 26th IEEE Photovoltaic Specialists Conference on Sep. 29-Oct. 3, 1997, in Anaheim, Calif., the publication proposed the technique of using a printed circuit as an interconnect to eliminate the need for stringing back contacted cells to create a module or device. However this method carries with it additional cost.

Another approach to cost reduction of PV devices is the use of optical components to concentrate light onto the cell. Using this technique less cell area is required to generate a specific amount of energy in a device. PV Cells are the largest single component of cost in a PV device, so reducing the need for these cells contributes to cost savings. PV devices have been developed and previously disclosed that use a rear reflector to concentrate light onto PV cells.

It would be desirable to at least partially address some or all of the concerns referred to herein to produce a more cost-effective PV device.

### SUMMARY

Many of the limitations described above are overcome in accordance with preferred embodiments of the present invention. Some preferred embodiments of the present invention combine the creation of a rear reflector in a concentrating PV device with the electrical connections between the various cells in the PV device to reduce the number of manufacturing steps and amount of materials required for producing the PV device. A variety of ways to form the electrical connections are described and claimed herein. In some preferred embodiments a masking layer is used to form a pattern in a conductive layer deposited onto the photovoltaic module, including gaps in the conductive layer, as is described in detail herein. Some preferred embodiments of the present invention include a parallel array of triangle prism concentrators (“triangular prism concentrator array”) optically coupled to photovoltaic cells, with the photovoltaic cells electrically connected to produce a useful voltage at the device's electrical terminals.

### DRAWINGS

### Drawing Figures

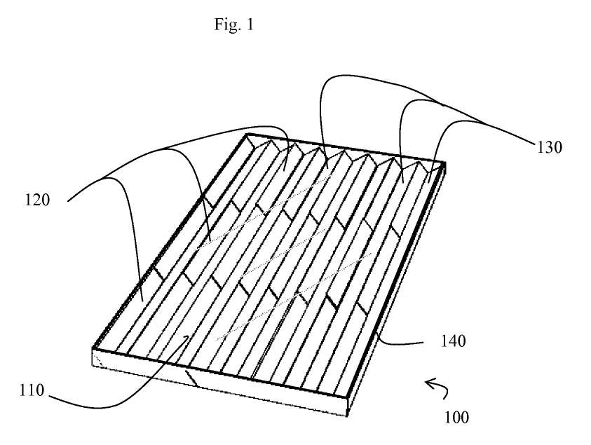

FIG. 1 is a perspective view of a triangular prism concentrator photovoltaic device;

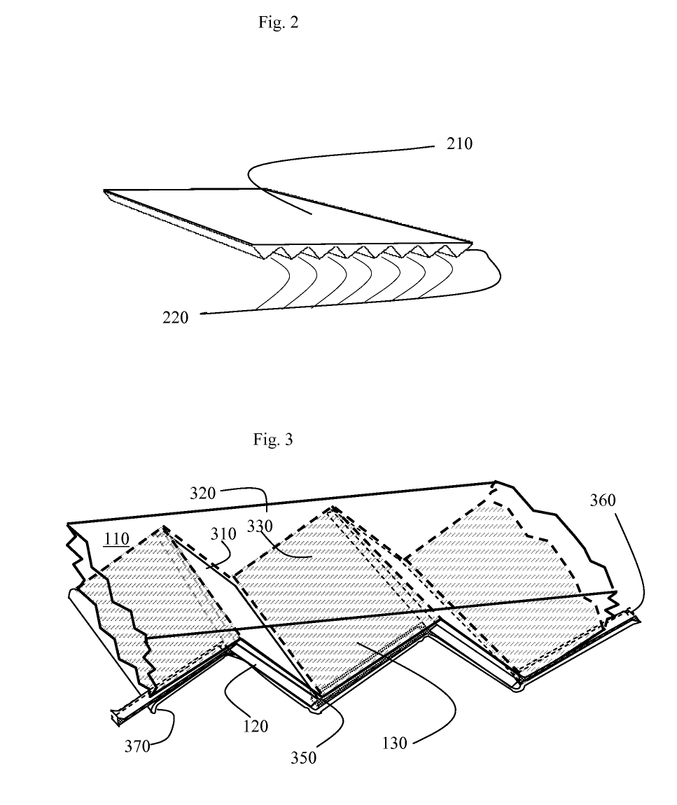

FIG. 2 is a perspective view of a triangular prism concentrator array;

FIG. 3 is a detailed perspective view of the triangular prism concentrator array;

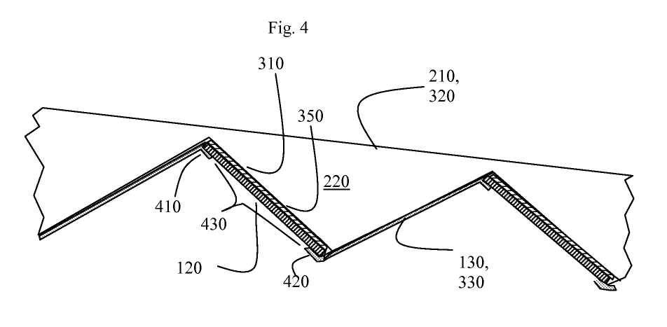

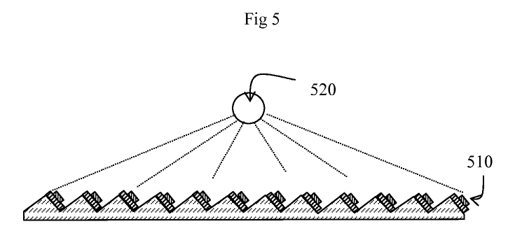

FIG. 4 is a detailed side-view of a triangular prism device;

FIG. 5 is a detailed side-view of a triangular prism device showing masking and metal deposition;

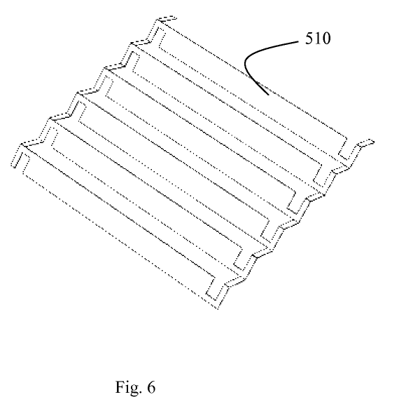

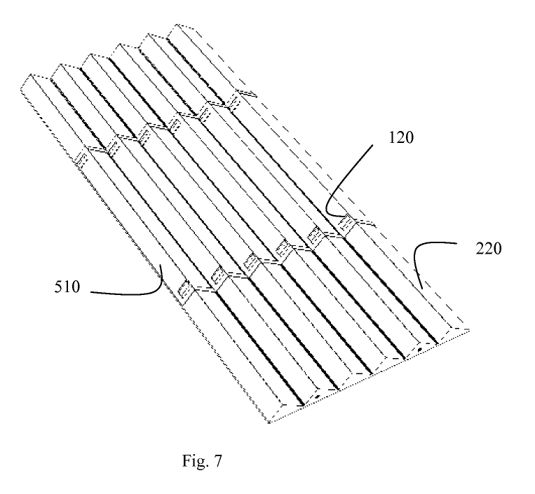

FIG. 6 is an isometric perspective view of a mask layer associated with a triangular prism concentrator array;

FIG. 7 is an isometric perspective view of a mask layer overlaying a triangular prism concentrator array prior to reflector deposition; and

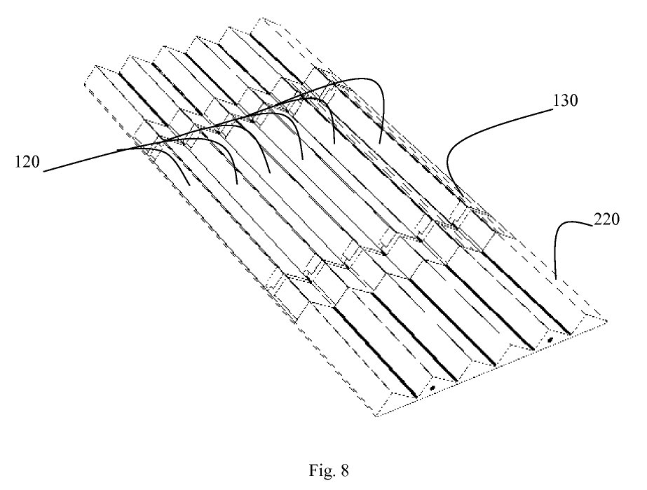

FIG. 8 is an isometric perspective view of a finished triangular prism concentrator array with a mask layer removed.

### REFERENCE NUMERALS IN DRAWINGS

100 Triangular prism concentrator array photovoltaic device
110 Front glass
120 PV cells
130 Reflectors
140 Module frame
210 Flat concentrator front surface
220 Multiple triangular prisms on concentrator back surface
310 First side of each triangular prism
320 Second side of each triangular prism
330 Third side of each triangular prism
350 Optical coupling gel
360 Electrical interconnect means
370 Encapsulant film
410 Back positive terminal
420 Back negative terminal
510 Masking material layer
520 Reflective and conductive material source

### DETAILED DESCRIPTION

FIG. 1 shows a triangular prism concentrator (TPC) array photovoltaic device 100. A description of the physical relationships between various components of the device 100 is included here in FIGS. 1-8 to aid in the understanding of the device 100 before describing in further detail an apparatus and method for electrically connecting cells in a photovoltaic (PV) device. FIGS. 2, 3 and 4 break out and enlarge components of device 100. A variety of methods for forming a useful, patterned electrically conductive layer to electrically connect photovoltaic cells to for the photovoltaic device are described.

One embodiment of the photovoltaic device of the present invention is illustrated in FIG. 1. FIG. 1 shows a triangular prism concentrator (TPC) array photovoltaic device 100. A brief description of the physical relationships between various components of the device 100 is included here to aid in the understanding of the device 100 before being described in greater detail. The description also references FIGS. 2, 3 and 4 which break out and enlarge components of device 100 illustrated in FIG. 1. The device 100 is made up of a front glass 110 with a flat front surface 210 and a back surface formed to create multiple triangular prisms 220. The flat front surface 210 acts as a second side of each triangular prism 320, as is described in detail below. Photovoltaic cells 120 are arrayed along a first side 310 of each of the prisms of the front glass 110. A second side 320 of each of the triangular prisms 220 is formed by the flat front surface 210 of the front glass 110. A reflective surface (Reflectors) 130 is added to a third side 330 of each triangular prism 220. The reflectors 130 may be formed by coating the third side 330 of each triangular prism 220 with a reflective material. A rigid frame 140 surrounds the device providing mechanical stiffness and offering a surface for bolting to rails mounted on a roof.

In some preferred embodiments, the front glass 110 is a molded or extruded clear material having an index of refraction greater than one and preferably between 1.48 and 1.52. In some preferred embodiments the front glass 110 is made of UV-enhanced polymethylmethacrylate Acrylic (PMMA). In some embodiments, the PMMA used in the front glass 110 is Atoglas VH Plexiglas produced by Atofina Chemicals, Inc., Philadelphia, Pa. However, in other embodiments the front glass 110 can be fabricated from materials such as glass or polycarbonate plastic, which are substituted for PMMA.

In some preferred embodiments the third side 330 of each prism 220 is coated with aluminum deposited by vacuum metallization to achieve a reflectance on the order of 95% to form the reflectors 130. However, the reflectors 130 may be made of any materials that can be formed into this shape and made to be highly reflective and conductive such as other metals, etc.

FIG. 3 is a detailed perspective view of the triangular prism concentrator array showing additional details of the prism assembly 100. An optical coupling gel 350 is used. The optical coupling gel 350 is a thixotropic gel with an index of refraction approximately equal to that of the material comprising front glass 110. The optical coupling gel 350 is sandwiched between photovoltaic cell 120 and the first side of each triangular prism 220 of the front glass 110. The optical coupling gel 350 is used in part as an adhesive to hold PV cell 120 in place, as well as an optical coupler, thereby eliminating any air gaps between PV cell 120 and the first side of each triangular prism 310 of the front glass 110. In some preferred embodiments the optical coupling gel is Lightspan SL-1246 optical coupling gel (thixotropic) from Lightspan, LLC, 14 Kendrick Road, Unit #2, Wareham, Mass. In other embodiments, Sylgard 184 Silicone rubber from The Dow Chemical Company, 901 Loveridge Road, Pittsburg, California or the Nye Optical OCK451 curable adhesive from Nye Optical Company, 10309 Centinella Drive, La Mesa, Calif., can be used as the optical coupling gel 350. In other preferred embodiments the optical coupling gel can be replaced by ethelyne vinyl acetate (EVA) which is available from multiple vendors.

The PV cells 120 are electrically connected to each other by electrical interconnection means 360. In preferred embodiments the PV cells 120 have two electrical connections on their back surface (facing away from front glass 110).

The entire back of device 100 is sealed with an encapsulant film 370. In some embodiments this encapsulant film is a polymer sheet like EVA, ETFE, or Tedlar™, in other embodiments encapsulant film 370 may be applied in vapor or liquid form and may be either a polymer, epoxy, glass, or silicon nitride, or any other material capable of sealing out moisture, withstanding temperatures of approximately 50 degrees Celsius and protecting the back of device 100 from abrasions.

In FIG. 4, as described above, the device 100 includes the front glass 110 with the flat front surface 210, 320 and back surfaces 310 and 330 formed to create multiple triangular prisms 220. Photovoltaic cells 120 are arrayed along the first side 310 of each of the prisms 220. The thixotropic clear gel 350 fills the space between the cell 120 and the prism 220.

The third side 330 of each of the triangular prisms 220 is coated with a reflective and conductive film to form reflector 130, as described herein. This film is both reflective and electrically conductive and extends to contact a back positive terminal 410 of each PV cell 120 to a back negative terminal 420 of the adjacent PV cell 120 forming an in-series electrical connection between the PV cells 120 to create the desired output voltage for the device 100, e.g., 18 volts. Back positive terminal 410 of each cell is separated from back negative terminal 420 of the same cell by a gap in the electrically conductive layer 430.

Turning to FIG. 5, in some embodiments, the PV cells 120, gel 350, and front glass 110 are first assembled together prior to the creation of reflector 130. In some preferred embodiments a masking material layer 510 is then placed so as to cover the space between the electrical contacts on the back of each of the PV cells 120 to prevent undesirable electrical connections being created in the next step, creating the gap in the electrically conductive layer 430. In the next step, the reflector 130, which is both reflective and electrically conductive, is then deposited on the entire back side of the assembly from a reflective material source 520. In some preferred embodiments the reflector is made primarily of aluminum. In some other preferred embodiments the reflector is made primarily of silver. Then the mask and overlying portions of the reflector 130 are removed, leaving both a reflective layer 130 and the desired electrical connections between each of the PV cells 120. In some alternative embodiments, the reflective and conductive material forming the reflective layer 130 is deposited first, then a protective positive masking layer 510 is deposited over the reflective layer 130. Finally those portions of the reflective layer 130 that are unprotected by the masking layer are etched away with chemicals, plasma or other known removing means to break undesirable electrical connections such as those between the back positive terminal 410 and back negative terminal 420 initially formed when the reflective layer was deposited. In some alternative embodiments the masking layer is also removed before the PV device 100 is complete. In all cases, forming the final reflective and conductive surfaces 130 are achieved by processes well known in the relevant arts.

In other alternative embodiments, the reflective and conductive material forming the reflective layer 130 is deposited in the desired pattern by directly writing or applying the reflective layer 130 in the desired pattern. In some embodiments this is accomplished by ink jet-like, electrostaticly-controlled, technology for depositing materials onto a surface, in this case, the PV cells 120.

Turning to FIGS. 6-8, in some preferred embodiments a process for forming the finished reflective and conductive layer 130 is shown in greater detail. In FIG. 6, the masking layer 510 is shown for use with the triangular prism concentrator array photovoltaic device 100. The masking layer 510 is formed by means, and made of materials, well known in the relevant arts. For example, the mask layer may be made from any suitable plastic. The masking layer is formed and placed onto the back surface of the PV array 100, closest to the first (310) and third (330) sides and furthest from the second (320) sides. In some preferred embodiments employing a liftoff method, the masking layer is what ultimately prevents the reflective and conductive coating in the next step from becoming attached to certain portions of the PV array 100 where improper electrical connections would otherwise form. In this sense the mask can be considered a negative mask because the reflective and conductive layer 130 is not deposited between the PV array 130 and the masking layer 510. In other embodiments a positive mask may be used as is known in the relevant arts.

In FIG. 7, the masking layer 510 is shown placed onto the PV cells 120, the PV cells 120 are attached to the multiple triangular prisms on concentrator back surface 220. With the masking layer 510 in place, in some preferred embodiments the reflective and conductive layer 130 is then deposited onto the PV array 100 and mask 510. The reflective and conductive layer 130 is preferably made of aluminum or silver. While aluminum or silver are preferred materials, it is envisioned that the reflective layer can also be made of many other metals, combinations of metals, or any materials that are or can be made reflective, conductive and can withstand the operating temperatures of the PV device 100, such as −20 to 100 degrees Centigrade.

The reflective and conductive layer 130 can be deposited onto the PV array 100 by a variety of methods known in the relevant arts. In some preferred embodiments the deposition is performed by the process of vapor deposition in which the assembly is placed in a vacuum chamber and an aluminum or silver filament 520 is heated to vaporize the aluminum or silver which then coats all exposed surfaces that are not masked. In some alternative embodiments the reflective and conductive layer 130 is deposited by sputtering, electroplating, electroless chemical plating or spray coating. The present invention is not limited to any particular method creating the reflective and conductive layer 130 and other known methods for depositing a thin layer of reflective and conductive material may be used as well.

Turning to FIG. 8, following the metal deposition step, the masking material 510 is removed leaving the electrically conductive and optically reflective layer 130 deposited on the desired portions of multiple triangular prisms on concentrator back surface 220, more specifically, the first side 310 and third side 330, in a pattern to form a series electrical connection between the PV cells 120 of the device 100. Other patterns corresponding to particular electrical connections, and hence particular voltages, can also be used. An electrically insulating backcoating is then applied to the surfaces previously covered by the mask 510 and reflective and conductive layer 130. In some preferred embodiments the backcoating may be EVA in a liquid two-part catalytic solution which is allowed to cure or in sheet form which is laminated to the PV array using a standard vacuum laminating process. Other known insulating coatings and other known techniques for applying all these coatings are envisioned by the present invention which is not limited to any particular coating or method of application.

It is understood that the forms of the invention shown and described in the detailed description and the drawings are to be taken merely as examples. It is intended that the following claims be interpreted broadly to embrace all the variations of the example embodiments disclosed herein. Thus the scope of the invention should be determined by the appended claims and their legal equivalents, rather than by the examples given.

What is claimed is:

1. A method for coupling a plurality of photovoltaic cells, comprising the steps of:
depositing an electrically conductive layer on the plurality of photovoltaic cells; and
forming a pattern in the electrically conductive layer, the pattern including gaps in the electrically conductive layer, to electrically couple at least some of the plurality of photovoltaic cells.

2. The method for coupling a plurality of photovoltaic cells of claim 1, further comprising:
placing a masking material over a portion of the plurality of photovoltaic cells to form a masked portion and an exposed portion on the plurality of photovoltaic cells.

3. The method for coupling a plurality of photovoltaic cells of claim 2, wherein the electrically conductive layer is deposited on the exposed portion on the plurality of photovoltaic cells and on the masking material, but is not substantially deposited on the masked portion of the plurality of photovoltaic cells.

4. The method for coupling a plurality of photovoltaic cells of claim 2, further comprising:
removing the masking material.

5. The method for coupling a plurality of photovoltaic cells of claim 2, wherein the electrically conductive layer is allowed to remain on the exposed portion on the plurality of photovoltaic cells and is removed from the masked portion of the plurality of photovoltaic cells.

6. The method for coupling a plurality of photovoltaic cells of claim 1, wherein the electrically conductive layer is patterned by first depositing the electrically conductive layer over a back surface of the plurality of photovoltaic cells, then using a masking material to form protected portions of the electrically conductive layer, then removing portions of the electrically conductive layer that are not the protected portions of the electrically conductive layer.

7. The method for coupling a plurality of photovoltaic cells of claim 5, wherein the step of removing portions of the electrically conductive layer that are not the protected portions is done by etching.

8. The method for coupling a plurality of photovoltaic cells of claim 1, wherein the step of depositing the electrically conductive layer also forms a reflective surface.

9. The method for coupling a plurality of photovoltaic cells of claim 1, wherein the step of depositing the electrically conductive layer deposits aluminum.

10. The method for coupling a plurality of photovoltaic cells of claim 1, wherein the step of depositing the electrically conductive layer deposits silver.

11. The method for coupling a plurality of photovoltaic cells of claim 1, wherein the step of depositing the electrically conductive layer employs vapor deposition.

12. The method for coupling a plurality of photovoltaic cells of claim 1, wherein the step of depositing the electrically conductive layer employs sputtering.

13. The method for coupling a plurality of photovoltaic cells of claim 1, wherein the step of depositing the electrically conductive layer employs electroplating.

14. The method for coupling a plurality of photovoltaic cells of claim 1, wherein the step of depositing the electrically conductive layer employs electroless chemical plating.

15. The method for coupling a plurality of photovoltaic cells of claim 1, wherein the step of depositing the electrically conductive layer employs spray coating.

16. The method for coupling a plurality of photovoltaic cells of claim 1, wherein the steps of depositing and forming the electrically conductive layer are performed by an electrostaticly-controlled device.

17. The method for coupling a plurality of photovoltaic cells of claim 1, wherein the plurality of photovoltaic cells are optically coupled to a light concentrator.

18. The method for coupling a plurality of photovoltaic cells of claim 17, wherein light concentrator further comprises an array of triangular prisms.
